(19) United States
(12) Patent Application Publication
(10) Pub. No.: US 2025/0204106 A1
(43) Pub. Date: Jun. 19, 2025

(54) LIGHT-EMITTING DEVICE AND IMAGE DISPLAY APPARATUS

(71) Applicant: SONY GROUP CORPORATION, Tokyo (JP)

(72) Inventor: Yuki MAEDA, Tokyo (JP)

(73) Assignee: SONY GROUP CORPORATION, Tokyo (JP)

(21) Appl. No.: 18/846,533

(22) PCT Filed: Mar. 9, 2023
(86) PCT No.: PCT/JP2023/009146

§ 371 Date: Sep. 12, 2024

(30) Foreign Application Priority Data
Mar. 31, 2022 (JP) 2022-059213

(51) Int. Cl. H10H 20/851; H10H 20/856

(52) U.S. Cl. CPC H10H 20/8515; H10H 20/8514; H10H 20/856

(57) ABSTRACT

A light-emitting device according to an embodiment of the present disclosure includes: a light source section that outputs excitation light; a support member that has optical transparency and that includes a first surface and a second surface opposed to each other; a wavelength converter including a plurality of three-dimensional structures each including a phosphor, each of the plurality of three-dimensional structures standing on the first surface of the support member and having a height in a standing direction equal to or larger than a width in an in-plane direction of the first surface; and a first spectroscopic film that is disposed on a first end surface side of the plurality of three-dimensional structures facing the first surface of the support member and that reflects light converted by wavelength conversion in the plurality of three-dimensional structures.

### TECHNICAL FIELD

The present disclosure relates to, for example, a light-emitting device that performs wavelength conversion of excitation light to output the light and to an image display apparatus.

### BACKGROUND ART

For example, in PTL 1, an organic EL element is disclosed that, with a transparent substrate provided with a microstructure layer on its surface, highly efficiently extracts light emission of an organic light-emitting layer to the outside.

### CITATION LIST

### Patent Literature

PTL 1: Japanese Unexamined Patent Application Publication No. JP2008-112592

### SUMMARY OF THE INVENTION

Meanwhile, in a light-emitting device used as a panel light source for an augmented reality (AR) headset or a compact projector, for example, enhancement in directivity is desired.

It is desirable to provide a light-emitting device and an image display apparatus that make it possible to enhance the directivity.

A light-emitting device according to one embodiment of the present disclosure includes: a light source section that outputs excitation light; a support member that has optical transparency and that includes a first surface and a second surface opposed to each other; a wavelength converter including a plurality of three-dimensional structures each including a phosphor, each of the plurality of three-dimensional structures standing on the first surface of the support member and having a height in a standing direction equal to or larger than a width in an in-plane direction of the first surface; and a first spectroscopic film that is disposed on a first end surface side of the plurality of three-dimensional structures facing the first surface of the support member and that reflects light converted by wavelength conversion in the plurality of three-dimensional structures.

An image display apparatus according to one embodiment of the present disclosure includes a plurality of pluralities of light-emitting devices arranged in an array. As the pluralities of light-emitting devices, the plurality of the light-emitting devices according to one embodiment described above is included.

In the light-emitting device according to one embodiment and the image display apparatus according to one embodiment of the present disclosure, a wavelength converter including a plurality of three-dimensional structures each including a phosphor, each of the plurality of three-dimensional structures standing on a first surface of the support member and having a height in a standing direction equal to or larger than a width in an in-plane direction of the first surface, and a first spectroscopic film that is disposed on a first end surface side of the plurality of three-dimensional structures facing the first surface of the support member and that reflects light converted by wavelength conversion in the plurality of three-dimensional structures are provided. With this, light converted by wavelength conversion in the plurality of three-dimensional structures is confined in the plurality of three-dimensional structures.

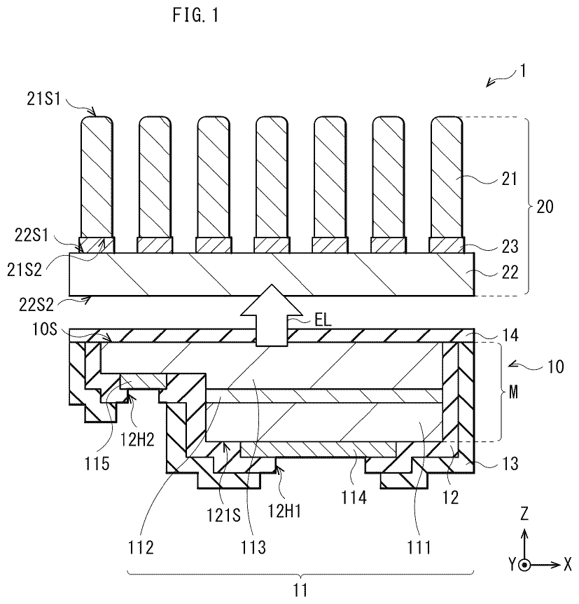

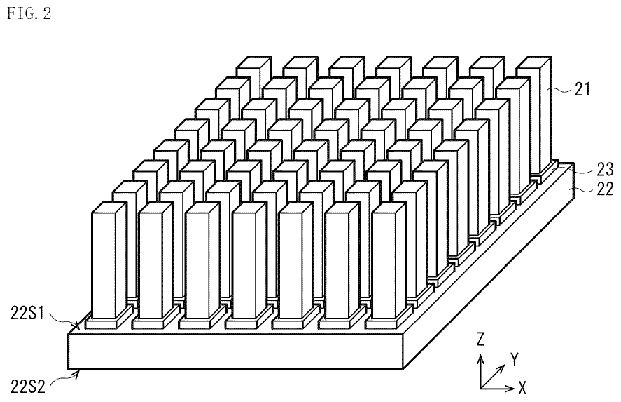

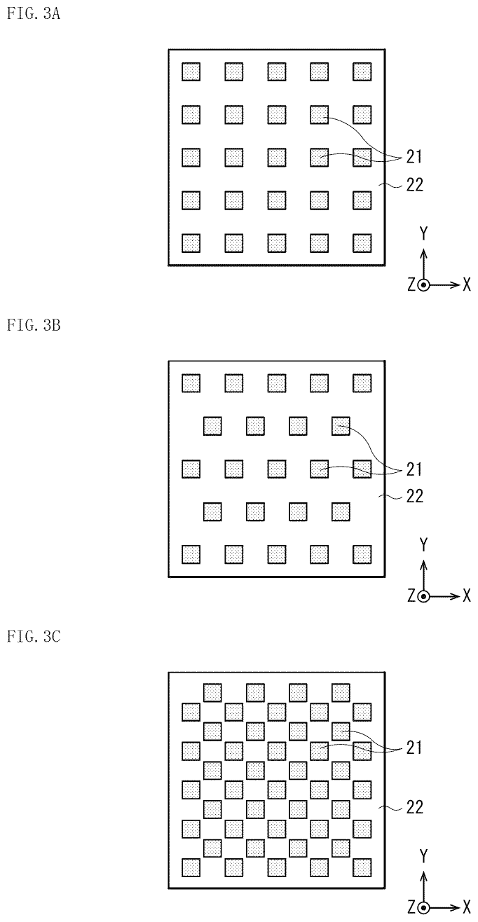

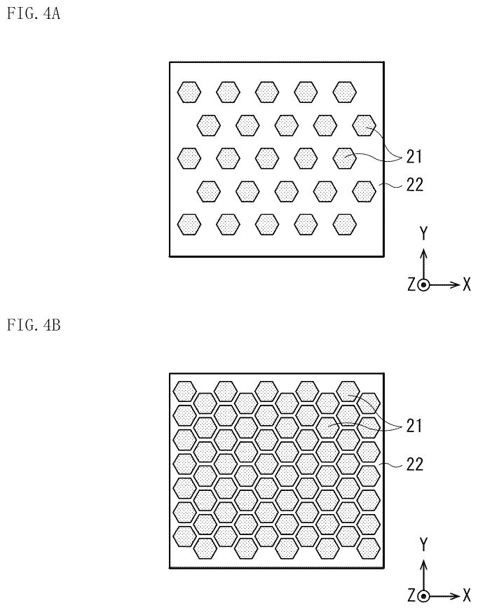

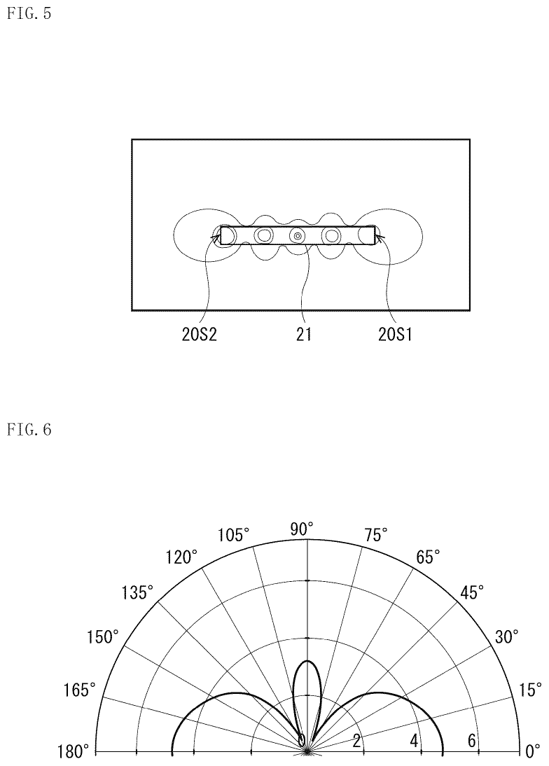

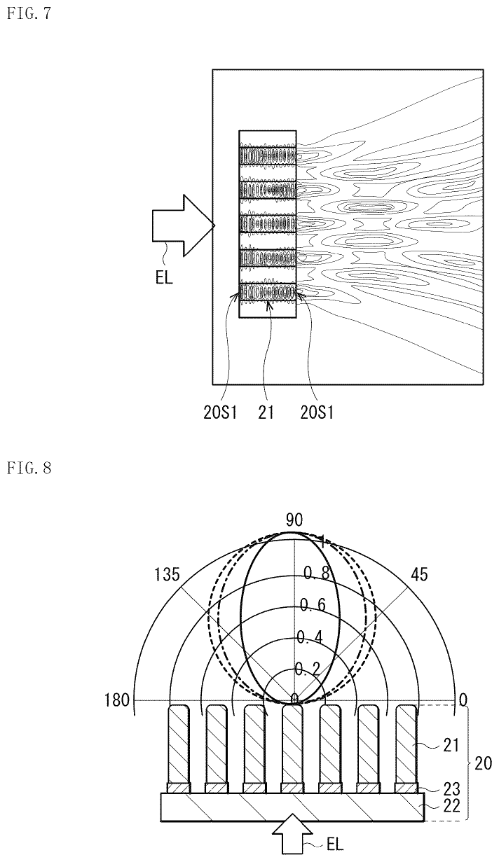

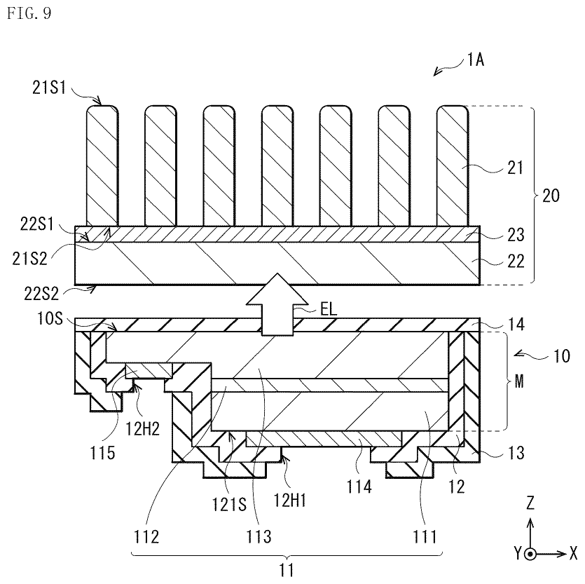

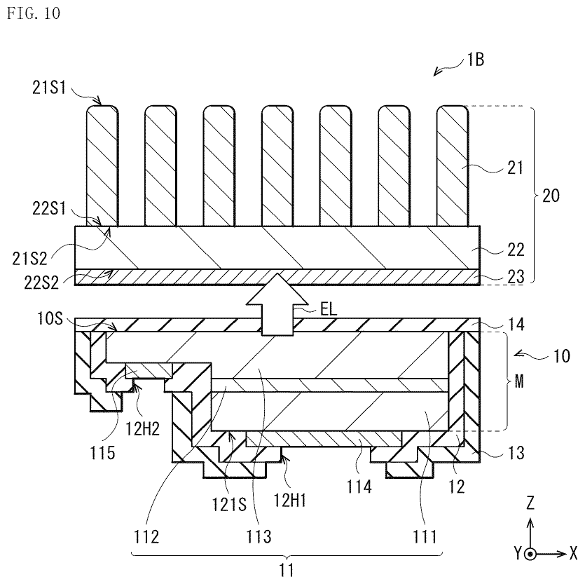

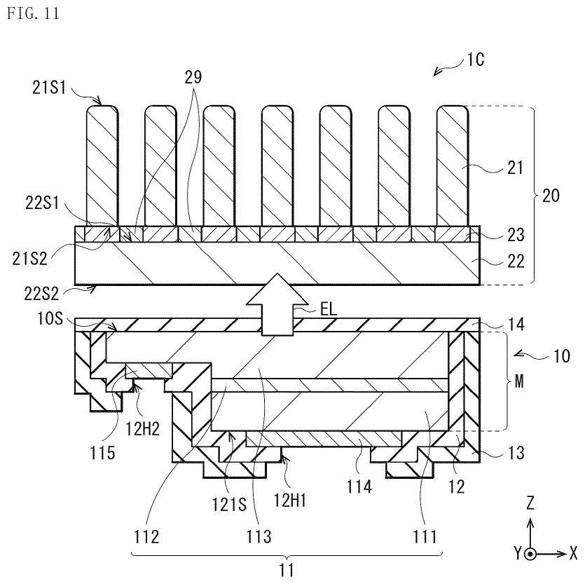

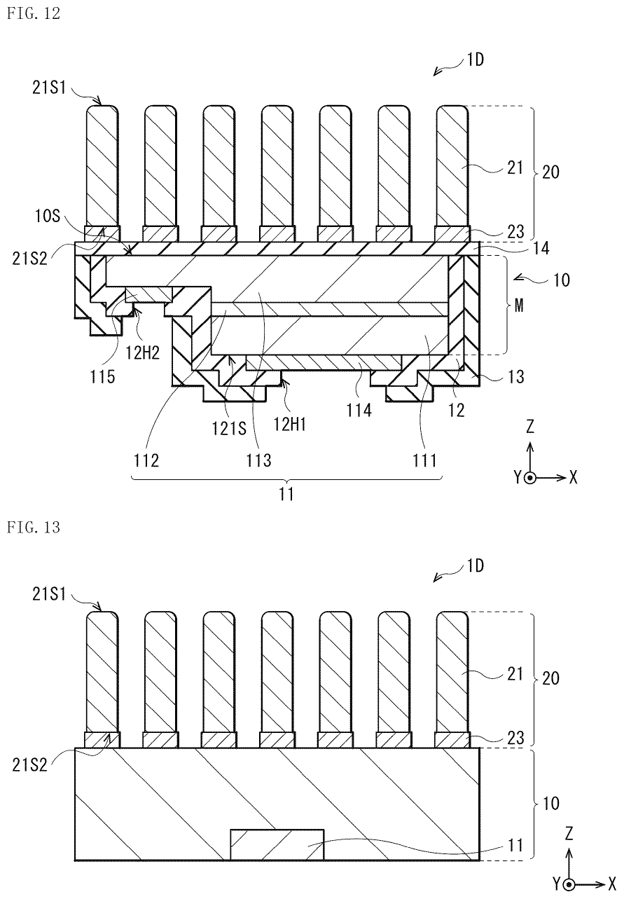

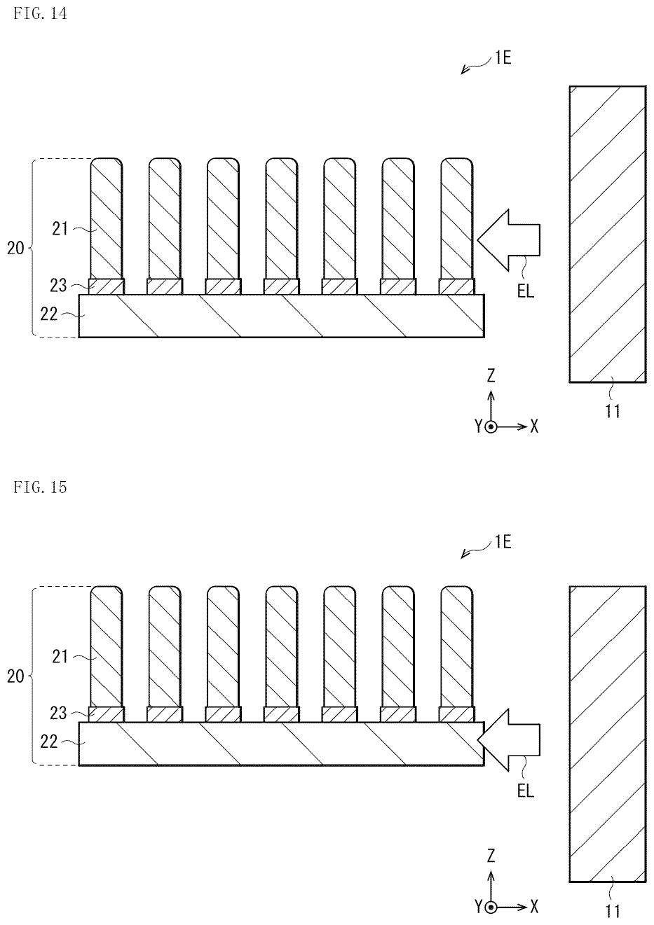

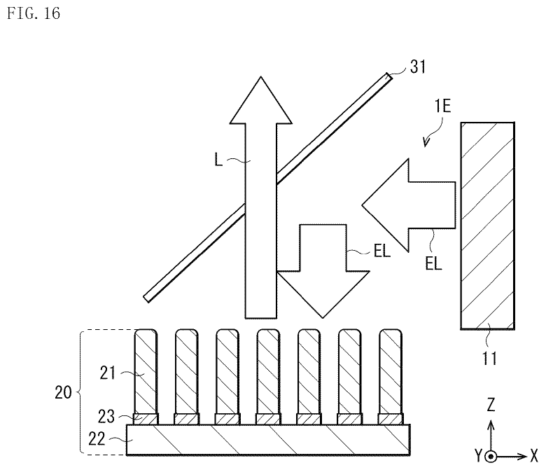

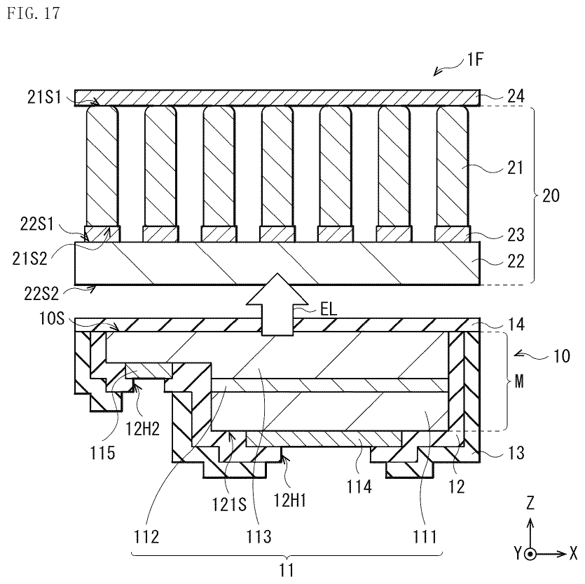

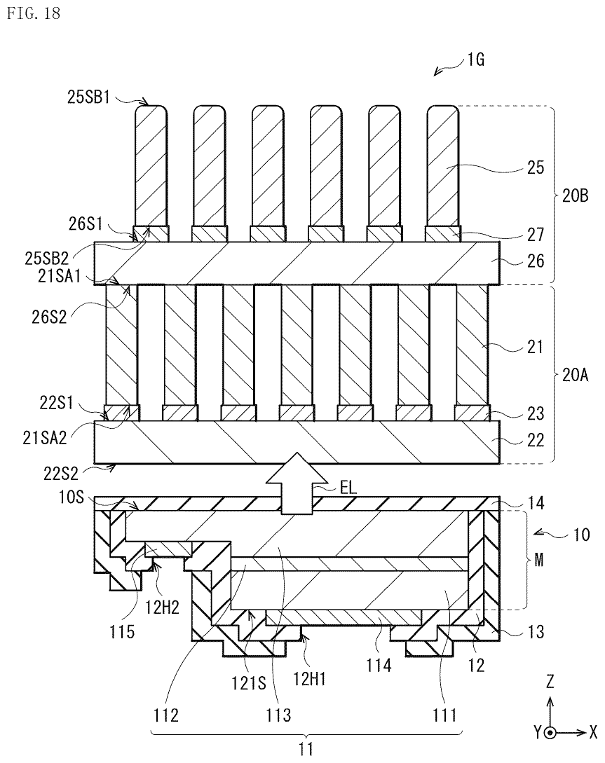

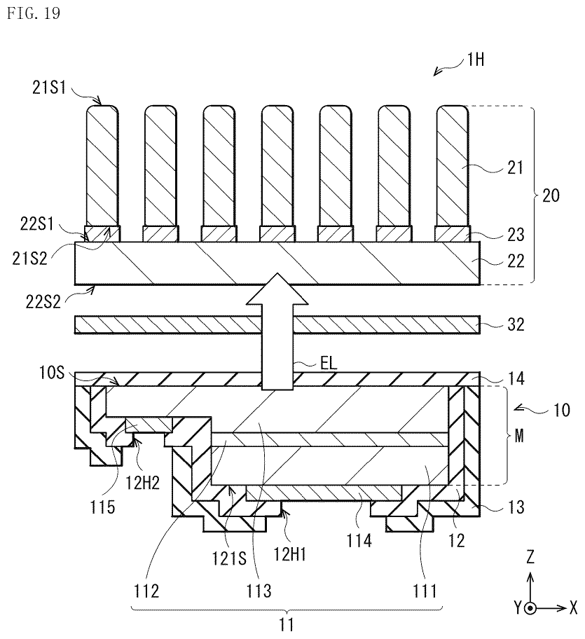

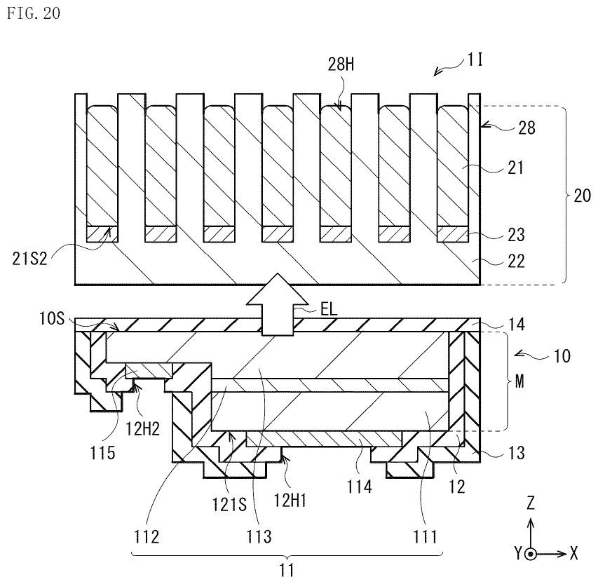

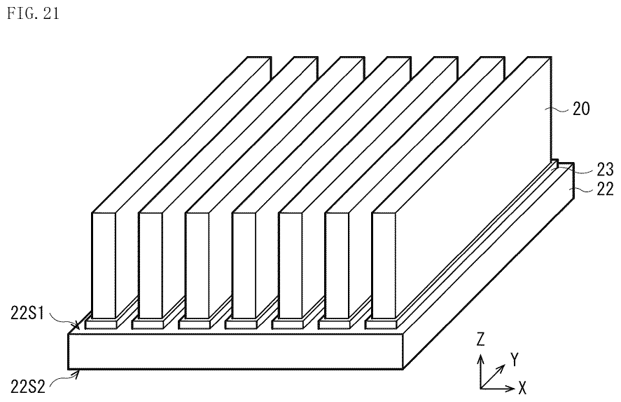

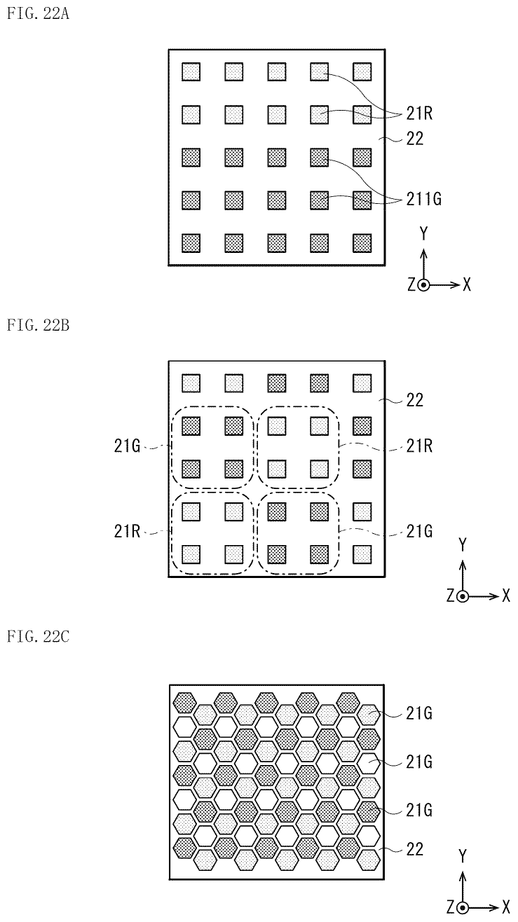

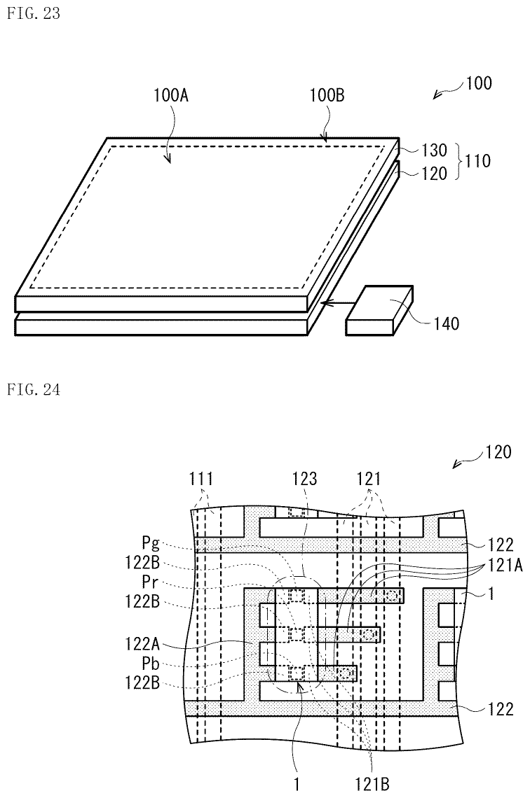

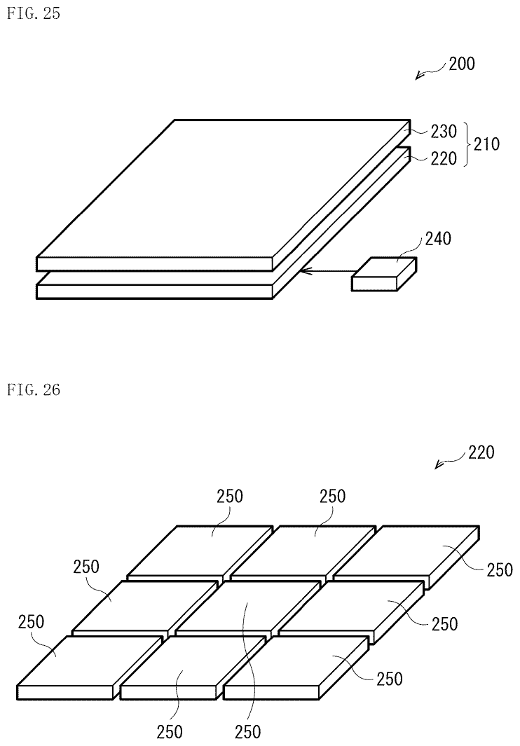

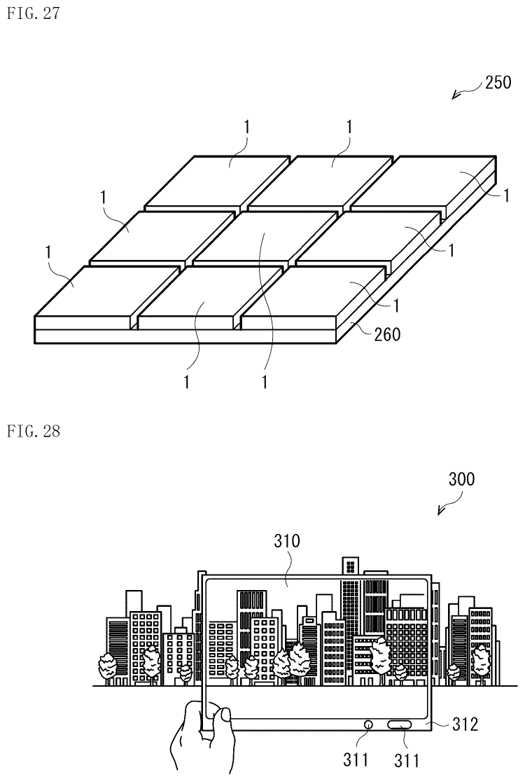

### BRIEF DESCRIPTION OF DRAWING

[FIG. 1] is a cross-sectional schematic diagram illustrating a configuration of a light-emitting device according to an embodiment of the present disclosure.

[FIG. 2] is a perspective diagram explaining a configuration of a wavelength converter illustrated in FIG. 1.

[FIG. 3A] is a diagram illustrating an example of a planar layout of a plurality of pillars included in the wavelength converter illustrated in FIG. 1.

[FIG. 3B] is a diagram illustrating another example of a planar layout of the plurality of pillars included in the wavelength converter illustrated in FIG. 1.

[FIG. 3C] is a diagram illustrating another example of a planar layout of the plurality of pillars included in the wavelength converter illustrated in FIG. 1.

[FIG. 4A] is a diagram illustrating another example of a planar layout of the plurality of pillars included in the wavelength converter illustrated in FIG. 1.

[FIG. 4B] is a diagram illustrating another example of a planar layout of the plurality of pillars included in the wavelength converter illustrated in FIG. 1.

[FIG. 5] is a Sim diagram (for illustrative purposes) explaining a light confinement effect in an individual pillar included in the wavelength converter illustrated in FIG. 1.

[FIG. 6] is an illumination distribution diagram of light output from an end surface of the individual pillar illustrated in FIG. 5.

[FIG. 7] is a Sim diagram (for illustrative purposes) illustrating electric field intensity distribution of the wavelength converter illustrated in FIG. 1.

[FIG. 8] is an illumination distribution diagram of light output from the light-emitting device illustrated in FIG. 1.

[FIG. 9] is a cross-sectional schematic diagram illustrating a configuration of a light-emitting device according to Modification 1 of the present disclosure.

[FIG. 10] is a cross-sectional schematic diagram illustrating a configuration of a light-emitting device according to Modification 2 of the present disclosure.

[FIG. 11] is a cross-sectional schematic diagram illustrating a configuration of a light-emitting device according to Modification 3 of the present disclosure.

[FIG. 12] is a cross-sectional schematic diagram illustrating an example of a configuration of a light-emitting device according to Modification 4 of the present disclosure.

[FIG. 13] is a cross-sectional schematic diagram illustrating another example of a configuration of the light-emitting device according to Modification 4 of the present disclosure.

[FIG. 14] is a cross-sectional schematic diagram illustrating an example of a configuration of a light-emitting device according to Modification 5 of the present disclosure.

[FIG. 15] is a cross-sectional schematic diagram illustrating another example of a configuration of the light-emitting device according to Modification 5 of the present disclosure.

[FIG. 16] is a cross-sectional schematic diagram illustrating another example of a configuration of the light-emitting device according to Modification 5 of the present disclosure.

[FIG. 17] is a cross-sectional schematic diagram illustrating a configuration of a light-emitting device according to Modification 6 of the present disclosure.

[FIG. 18] is a cross-sectional schematic diagram illustrating an example of a configuration of a light-emitting device according to Modification 7 of the present disclosure.

[FIG. 19] is a cross-sectional schematic diagram illustrating a configuration of a light-emitting device according to Modification 8 of the present disclosure.

[FIG. 20] is a cross-sectional schematic diagram illustrating an example of a configuration of a light-emitting device according to Modification 9 of the present disclosure.

[FIG. 21] is a perspective diagram illustrating an example of a configuration of a wavelength converter according to Modification 10 of the present disclosure.

[FIG. 22A] is a planar schematic diagram explaining an example of a configuration of a plurality of pillars included in a wavelength converter according to Modification 11 of the present disclosure.

[FIG. 22B] is a planar schematic diagram explaining another example of a configuration of the plurality of pillars included in the wavelength converter according to Modification 11 of the present disclosure.

[FIG. 22C] is a planar schematic diagram explaining another example of a configuration of the plurality of pillars included in the wavelength converter according to Modification 11 of the present disclosure.

[FIG. 23] is a perspective diagram illustrating an example of a configuration of an image display apparatus according to Application Example 1 of the present disclosure.

[FIG. 24] is a schematic diagram illustrating an example of a layout of the image display apparatus illustrated in FIG. 23.

[FIG. 25] is a perspective diagram illustrating an example of a configuration of an image display apparatus according to Application Example 2 of the present disclosure.

[FIG. 26] is a perspective diagram illustrating a configuration of a mounting substrate illustrated in FIG. 25.

[FIG. 27] is a perspective diagram illustrating a configuration of a unit substrate illustrated in FIG. 26.

[FIG. 28] is a diagram illustrating an example of an image display apparatus according to Application Example 3 of the present disclosure.

### MODES FOR CARRYING OUT THE INVENTION

In the following, embodiments of the present disclosure will be described in detail with reference to the drawings. The following description is a specific example of the present disclosure, and the present disclosure is not limited to the following aspects. Further, with respect to an arrangement, a size, a proportion, and the like of each component illustrated in the drawings, the present disclosure is by no means limited to these. Note that the description will be given in the following order.
1. Embodiments (Example of Light-emitting Device with Spectroscopic Film Disposed on End Surface Opposite to Light Output Surface of Wavelength Converter Including Plurality of Three-dimensional Structures)
2. Modification 1 (Another Example of Light-emitting Device)
3. Modification 2 (Another Example of Light-emitting Device)
4. Modification 3 (Another Example of Light-emitting Device)
5. Modification 4 (Another Example of Light-emitting Device)
6. Modification 5 (Another Example of Light-emitting Device)
7. Modification 6 (Another Example of Light-emitting Device)
8. Modification 7 (Another Example of Light-emitting Device)
9. Modification 8 (Another Example of Light-emitting Device)
10. Modification 9 (Another Example of Light-emitting Device)
11. Modification 10 (Another Example of Configuration of Wavelength Converter)
12. Modification 11 (Another Example of Configuration of Wavelength Converter)
13. Application Example 1 (Example of Image Display Apparatus)
14. Application Example 2 (Example of Image Display Apparatus)
15. Application Example 3 (Example of Image Display Apparatus)

### 1. Embodiments

FIG. 1 is a diagram illustrating an example of a schematic cross-sectional configuration of a light-emitting device (light-emitting device 1) according to an embodiment of the present disclosure. The light-emitting device 1 is, for example, suitably used for a display pixel 123 of an image display apparatus (for example, image display apparatus 100, see FIG. 23).

The light-emitting device 1 according to the present embodiment includes a light source section 10 and a wavelength converter 20 disposed on a light extraction surface (surface 10S) side of the light source section 10. The wavelength converter 20 has a configuration that a plurality of pillars 21 is disposed standing on a surface 22S1 of a support member 22 including a pair of surfaces (the surface 22S1 and a surface 22S2) opposite to each other and a spectroscopic film 23 is disposed between each of the plurality of pillars 21 and the support member 22. The plurality of pillars 21 corresponds to a specific example of a “plurality of three-dimensional structures” in the present disclosure, and the spectroscopic film 23 corresponds to a specific example of a “first spectroscopic film” in the present disclosure.

### [Configuration of Light-Emitting Device]

A configuration of the light-emitting device 1 will be described below.

The light source section 10 includes a light-emitting element 11 as a light source.

The light-emitting element 11 is a solid light-emitting element that emits light in a predetermined wavelength bandwidth from the light extraction surface (surface 10S), the light-emitting element 11 being, for example, a light emitting diode (LED) chip. The LED chip refers to one in a state taken out from a wafer used for crystal growth, not one of a package-type covered with molded resin or the like. The LED chip has, for example, a size of 5 μm or more and 100 μm or less and is so-called micro LED.

The light-emitting element 11 includes, for example, a first electric conductivity type layer 111, an active layer 112, and a second electric conductivity type layer 113 that are stacked in this order. An upper surface of the second electric conductivity type layer 113 is the light extraction surface and corresponds to, for example, a light extraction surface 11S of the light source section 10. The light-emitting element 11 includes a mesa part M in, for example, a columnar shape including the first electric conductivity type layer 111 and the active layer 112. The light-emitting element 11 includes, on a surface side opposite to the light extraction surface, a level difference including a protrusion exposing the first electric conductivity type layer 111 and a recess exposing the second electric conductivity type layer 113. In the present embodiment, the surface that includes the protrusion and the recess and that is opposite to the light extraction surface is referred to as a lower surface. The light-emitting element 11 further includes a first electrode 114 electrically connected to the first electric conductivity type layer 111 and a second electrode 115 electrically connected to the second electric conductivity type layer 113. Each of the first electrode 114 and the second electrode 115 is provided on the lower surface side. Specifically, the first electrode 114 is provided on the first electric conductivity type layer, on the protrusion of the lower surface and the second electrode 115 is provided on the second electric conductivity type layer, on the recess of the lower surface.

The first electric conductivity type layer 111 is formed of, for example, a GaN-based semiconductor material of p-type. The active layer 112 has a multi-quantum well structure that, for example, InGaN and GaN are alternately stacked. The active layer 112 includes a light-emitting region in the layer. From the active layer 112, for example, light (blue light) in a blue bandwidth of 430 nm or more and 500 nm or less is extracted. In addition, for example, light (ultraviolet ray) with a wavelength corresponding to an ultraviolet region of 360 nm or more and 430 nm or less may be extracted from the active layer 112. The second electric conductivity type layer 113 is formed of, for example, a GaN-based semiconductor material of n-type.

The first electrode 114 is in contact with the first electric conductivity type layer 111 and is electrically connected to the first electric conductivity type layer 111. In other words, the first electrode 114 is in ohmic contact with the first electric conductivity type layer 111. The first electrode 114 is, for example, a metal electrode and is configured as a multilayer film (Ni/Au) including nickel (Ni) and gold (Au), for example. Alternatively, the first electrode 114 may be formed using a transparent electric conductive material such as an indium tin oxide (ITO), for example.

The second electrode 115 is in contact with the second electric conductivity type layer 113 and is electrically connected to the second electric conductivity type layer 113. In other words, the second electrode 115 is in ohmic contact with the second electric conductivity type layer 113. The second electrode 115 is, for example, a metal electrode and is configured as a multilayer film (Ti/Al) including titanium (Ti) and aluminum (Al) or a multilayer film (Cr/Au) including chromium (Cr) and gold (Au), for example. Alternatively, the second electrode 115 may be formed using a transparent electric conductive material such as an ITO, for example.

Side surfaces of the first electric conductivity type layer 111, the active layer 112, and the second electric conductivity type layer 113 of the light-emitting element 11 are covered with an insulation film 12 and a reflection film 13.

The insulation film 12 is, for example, extended from the side surface of the light-emitting element 11 to peripheries of the first electrode 114 and the second electrode 115. The first electrode 114 and the second electrode 115 are respectively exposed to the outside through an opening 12H1 provided on the first electrode 114 and through an opening 12H2 provided on the second electrode 115.

The insulation film 12 provides electrical insulation between the reflection film 13 and the first electric conductivity type layer 111, the active layer 112, and the second electric conductivity type layer 113. The insulation film 12 is preferable to be formed using a transparent material with respect to light emitted from the active layer 112. Such a material includes, for example, silicon oxide (SiO₂), silicon nitride (Si₃N₄), aluminum oxide (Al₂O₃), titanium oxide (TiO₂), and titanium nitride (TiN). Alternatively, an organic material may be used. The thickness of the insulation film 12 is, for example, approximately 50 nm to 1 μm. The insulation film 12 is possible to be formed by, for example, a thin film deposition process such as chemical vapor deposition (CVD) method, vapor deposition, or sputtering.

The reflection film 13 reflects light emitted from the active layer 112. The reflection film 13 is provided covering the side surface of the light-emitting element 11 interposing the insulation film 12. Specifically, the reflection film 13 is formed extended on the side surface and the lower surface of the light-emitting element 11, reaching, for example, portions slightly retreated from an end of the insulation film 12 at the opening 12H1 and opening 12H2 of the insulation film 12.

The reflection film 13 is preferable to be formed using a material having a high reflectance with respect to light emitted from the active layer 112, regardless of the incident angle. Such a material includes, for example, titanium (Ti), aluminum (Al), silver (Ag), copper (Cu), gold (Au), nickel (Ni), platinum (Pt), and alloys of these. Alternatively, the reflection film 13 may be formed using a dielectric multilayer film. The thickness of the reflection film 13 is, for example, approximately 50 nm to 1 μm. The reflection film 13 is possible to be formed by, for example, a thin film deposition process such as CVD method, vapor deposition, or sputtering.

The light extraction surface (surface 10S) of the light-emitting element 11 is provided with a protection layer 14 that protects the light extraction surface of the light-emitting element 11. The protection layer 14 is formed of, for example, silicon oxide (SiO₂) or silicon nitride (Si₃N₄).

Besides the LED described above, for example, an LED (OLED) using an organic semiconductor or a semiconductor laser (Laser Diode (LD)) is possible to be used for the light source section 10.

The wavelength converter 20 is disposed on the surface 10S side of the light source section 10. The wavelength converter 20 includes the plurality of pillars 21 disposed standing on the surface 22S1 of the support member 22, as illustrated in FIG. 2, and includes the spectroscopic film 23 between each of the plurality of pillars 21 and the support member 22.

Each of the plurality of pillars 21 converts light (excitation light EL) output from the light source section 10 into light with a predetermined wavelength (for example, red (R)/green (G)/blue (B)) to output the light. Each of the plurality of pillars 21 has, for example, a columnar shape with a height (h) in a standing direction (Z-axis direction) equal to or larger than a width (W) in an in-plane direction (X-Y plane direction) of the support member 22, for example as illustrated in FIGS. 1 and 2. Each of the pillars 21 has a width (W) of 50 nm or wider and several m or narrower, for example. Each of the pillars 21 has a height (h) of 1 μm or higher and several tens of m or lower, for example. Note that each of the plurality of pillars 21 is not limited to a cylindrical shape or a polygonal prism shape with a width constant in the standing direction, but may have, for example, a conical shape, a polygonal cone shape, a truncated cone shape, a truncated polygonal cone shape, or the like.

FIGS. 3A to 3C and FIGS. 4A and 4B are each a diagram illustrating an example of a planar layout of the plurality of pillars standing on the surface 22S1 of the support member 22. The plurality of pillars 21 are arranged in an array in, for example, the row direction (X-axis direction) and column direction (Y-axis direction), at predetermined intervals, as illustrated in FIGS. 2 and 3A, for example. Alternatively, the plurality of pillars 21 may be arranged in a layout that the pillars are shifted, for example, in the X-axis direction by one pillar 21 every row, at predetermined intervals, as illustrated in FIG. 3B, for example. The plurality of pillars 21 may be arranged in hound's tooth check-like, as illustrated in FIG. 3C, for example. Alternatively, the plurality of pillars 21 may each have, for example, a hexagonal shape in plan view, and may be arranged in honeycomb-shape, as illustrated in FIGS. 4A and 4B, for example.

The plurality of pillars 21 is possible to be formed using phosphors such as quantum dot phosphors or inorganic phosphors, for example. Alternatively, the plurality of pillars 21 may be formed using organic dyes. For example, the plurality of pillars 21 may be formed in a bulk form without using any binder or formed with using a binder. In a case where the plurality of pillars 21 is formed using phosphors, the particle diameter of each phosphor is preferably several nm to several tens of nm, more preferably several nm to a desired wavelength order. This allows light scattering due to a phosphor particle to be reduced, enhancing the light confinement effect described below.

For example, in each of color pixels Pr, Pg, and Pb included in the display pixel 123, in the image display apparatus 100 described below, the plurality of pillars 21 that converts light output from the light source section 10 into light in a corresponding wavelength bandwidth is provided. Specifically, in the red color pixel Pr, a plurality of pillars 21R that converts light output from the light source section 10 into light (red light) in a red bandwidth is provided. In the green color pixel Pg, a plurality of pillars 21G that converts light output from the light source section 10 into light (green light) in a green bandwidth is provided. In the blue color pixel Pb, a plurality of pillars 21B that converts light output from the light source section 10 into light (blue light) in a blue bandwidth is provided.

The plurality of pillars 21R, the plurality of pillars 22G, and the plurality of pillars 22B are possible to be formed using, for example, quantum dot phosphors corresponding to the respective colors. Specifically, in a case of obtaining red light, the quantum dot phosphors are possible to be selected from, for example, InP, GaInP, InAsP, CdSe, CdZnSe, CdTeSe, AgInS₂, CuInS₂, CdTe, or the like. In a case of obtaining green light, the quantum dot phosphors are possible to be selected from, for example, InP, GaInP, ZnSeTe, ZnTe, CdSe, CdZnSe, CdS, AgInS₂, CuInS₂, CdSeS, or the like. In a case of obtaining blue light, the quantum dot phosphors are possible to be selected from ZnSe, ZnTe, ZnSeTe, CdSe, CdZnSe, CdS, CdZnS, AgInS₂, CuInS₂, CdSeS, or the like. Note that, in a case where blue light is output from the light source section 10 as described above, the plurality of blue pillars 21B may be omitted or may be formed using a resin layer having optical transparency.

The plurality of pillars 21 is possible to be formed using, for example, nanoimprint. Alternatively, the plurality of pillars 21 is possible to be formed by photolithography and etching, a 3D printer, or the like.

The support member 22 supports the plurality of pillars 21 included in the wavelength converter 20 and the spectroscopic film 23 provided for each of the plurality of pillars 21. The support member 22 has optical transparency and is, for example, a plate-shaped member. The support member 22 includes a pair of the surfaces 22S1 and 22S2 opposite to each other. Examples of the support member 22 includes a glass substrate such as of quartz, a crystal and ceramic substrate including sapphire, alumina, SiN, or SiC, and a resin substrate such as of methacrylc (PMMA) resin, acrylic resin, or silicone resin.

The spectroscopic film 23 selectively reflects light converted by wavelength conversion in the pillars 21. The spectroscopic film 23 is provided on an end surface (surface 21S2) of each of the plurality of pillars 21 facing the surface 22S1 of the support member 22. The spectroscopic film 23 includes, for example, a dielectric multilayer film or an organic multilayer film.

FIG. 5 is a Sim diagram (diagram for illustrative purposes) explaining a light confinement effect in any one of the pillars 21. With respect to light entered the pillar 21, standing waves are observed by Sim as illustrated in FIG. 5, allowing the light confinement effect in the pillar 21 to be seen. The light confined in the pillar 21 is re-output from both end surfaces (surface 21S1 and surface 21S2) of the pillar 21, providing illumination distribution with directivity as illustrated in FIG. 6, for example.

FIG. 7 is a Sim diagram (diagram for illustrative purposes) illustrating, as an example, electric field intensity distribution of the wavelength converter 20 that includes the plurality of pillars 21, each having a width of 500 nm, disposed standing thereon at intervals of 500 nm and that includes the spectroscopic film 23 provided on the surface 21S2 side. FIG. 8 illustrates illumination distribution of light output from the light-emitting device 1 according to the present embodiment. A typical light-emitting device including a wavelength conversion layer in solid film-like disposed on a light source section provides Lambertian light (D₀) as illustrated in FIG. 8. Even in a case where a microlens is disposed upper than the wavelength conversion layer, distribution of light is controlled in law of etendue, and thus distribution of light (D₁) with slight directivity as illustrated in FIG. 8 is provided. In contrast, the light-emitting device 1 according to the present embodiment provides, with the confinement in the plurality of pillars 21 and the re-outputting, distribution of light (D2) with high directivity as illustrated in FIG. 8. This allows efficiency in light utilization to be enhanced in an optical system disposed in the latter stage, for example.

Further, with polarization occurred in the rod-shaped three-dimensional structures such as the pillars 21, light output from the pillars 21 is polarized. Thus, with the light-emitting element 11 that emits polarized light such as a light-emitting diode (LD) used, for the light source section 10, light emission with stronger polarization is possible to be obtained.

### Operations and Effects

In the light-emitting device 1 according to the present embodiment, the wavelength converter 20 is disposed on the light extraction surface (surface 10S) side of the light source section 10. The wavelength converter 20 includes the plurality of pillars 21 disposed standing on the surface 22S1 of the support member 22 including a pair of surfaces (the surface 22S1 and surface 2252) opposite to each other and includes the spectroscopic film 23 disposed between each of the plurality of pillars 21 and the support member 22. With this, light converted by wavelength conversion in the plurality of pillars 21 is confined in the respective pillars 21. This will be described below.

In recent years, as a panel light source for an augmented reality (AR) headset or a compact projector, a microdisplay in a compact size with high efficiency is desired to be developed. Light emission of a typical light-emitting device provides Lambertian light emission with a large divergence angle, as described above. This may cause efficiency in light utilization to be low in an optical system disposed in the latter stage or the optical system to be large in size.

In view of this, in the present embodiment, for example, the wavelength converter 20 is disposed on the light extraction surface (surface 10S) side of the light source section 10, the wavelength converter 20 including the plurality of pillars 21 that is disposed standing on the surface 22S1 of the support member 22 including a pair of surfaces (the surface 22S1 and surface 22S2) and that is provided with the spectroscopic film 23 on the end surface (surface 21S2) facing the surface 22S1 of the support member 22. With this, light converted by wavelength conversion in the plurality of pillars 21 is confined in the respective pillars 21 and is re-output from the surface 21S1 opposite to the surface 21S2.

As described above, the light-emitting device 1 according to the present embodiment allows high directional light emission larger than that of a light-emitting device including a microlens disposed upper than the wavelength conversion layer to be obtained.

Further, the light-emitting device 1 according to the present embodiment allows efficiency in light utilization to be enhanced in an optical system disposed in the latter stage. Further, this allows power consumption to be reduced in a product including the light-emitting device according to the present embodiment.

Next, Modification 1 to Modification 11 of the present disclosure will be described. Note that a component corresponding to that of the light-emitting device 1 according to the embodiment described above is denoted by the same reference sign and the description of the component is omitted.

### 2. Modification 1

FIG. 9 illustrates an example of a schematic cross-sectional configuration of a light-emitting device 1A according to Modification 1 of the present disclosure. Similarly to the light-emitting device 1 in the embodiment described above, the light-emitting device 1A is, for example, suitably used for the display pixel 123 of the image display apparatus 100.

In the embodiment described above, an example is described in which the spectroscopic film 23 is individually provided between one end surface (surface 21S2) of each of the plurality of pillars 21 included in the wavelength converter 20 and the surface 22S1 of the support member 22, however the present disclosure is not limited to this. For example, as illustrated in FIG. 9, the spectroscopic film 23 may be provided over a whole surface of the surface 22S1 of the support member 22.

As described above, in the light-emitting device 1A of the present modification, the spectroscopic film 23 is provided over the whole surface of the surface 22S1 of the support member 22. Thus, this allows the manufacturing cost to be reduced, as compared with a case where the spectroscopic film 23 is individually provided for each of the plurality of pillars 21 as in the light-emitting device 1 of the embodiment described above.

### 3. Modification 2

FIG. 10 illustrates an example of a schematic cross-sectional configuration of a light-emitting device 1B according to Modification 2 of the present disclosure. Similarly to the light-emitting device 1 in the embodiment described above, the light-emitting device 1B is, for example, suitably used for the display pixel 123 of the image display apparatus 100.

In Modification 1 described above, an example is described in which the spectroscopic film 23 is provided over the whole surface of the surface 22S1 of the support member 22, however the present disclosure is not limited to this. For example, as illustrated in FIG. 10, the spectroscopic film 23 may be provided on the surface 22S2 side of the support member 22.

As described above, in the light-emitting device 1B of the present modification, the spectroscopic film 23 is provided over a whole surface of the surface 22S2 of the support member 22. Thus, this allows intensity distribution of light output from the wavelength converter 20 to be uniformed, as compared with the light-emitting device 1 of the embodiment described above or the like.

### 4. Modification 3

FIG. 11 illustrates an example of a schematic cross-sectional configuration of a light-emitting device 1C according to Modification 3 of the present disclosure. Similarly to the light-emitting device 1 in the embodiment described above, the light-emitting device 1C is, for example, suitably used for the display pixel 123 of the image display apparatus 100.

As in the embodiment described above, in a case where the spectroscopic film 23 is individually provided between one end surface (surface 21S2) of each of the plurality of pillars 21 included in the wavelength converter 20 and the surface 22S1 of the support member 22, for example, a light shielding film 29 that blocks the excitation light EL may be provided on the surface 22S1 of the support member 22 where the spectroscopic film 23 is not provided.

As described above, in the light-emitting device 1C of the present modification, the light shielding film 29 is provided between the spectroscopic films 23 each individually provided for a respective one of the plurality of pillars 21 on the surface 22S1 of the support member 22. With this, output of the excitation light EL having not entered the plurality of pillars 21 included in the wavelength converter 20 is reduced. Thus, color purity of light output from the light-emitting device 1C is possible to be enhanced.

### 5. Modification 4

FIG. 12 illustrates an example of a schematic cross-sectional configuration of a light-emitting device 1D according to Modification 4 of the present disclosure. FIG. 13 illustrates another example of a schematic cross-sectional configuration of the light-emitting device 1D according to Modification 4 of the present disclosure. Similarly to the light-emitting device 1 in the embodiment described above, the light-emitting device 1D is, for example, suitably used for the display pixel 123 of the image display apparatus 100.

In the embodiment described above, an example is described in which the plurality of pillars 21 and the spectroscopic film 23 that are included in the wavelength converter 20 are provided on the support member 22, however the present disclosure is not limited to this. For example, as illustrated in FIG. 12, the plurality of pillars 21 and the spectroscopic film 23 may be provided directly on, for example, the protection layer 14 provided on the light extraction surface 10S of the light-emitting element 11.

Further, in the embodiment described above, an example using an LED chip as the light-emitting element 11 is described, but the light-emitting element 11 of a package-type covered, for example, with molted resin or the like, for example as illustrated in FIG. 13, may be used and the plurality of pillars 21 and the spectroscopic film 23 may be provided directly on an upper surface of the package.

As described above, in the light-emitting device 1D of the present modification, the plurality of pillars 21 and the spectroscopic film 23 are provided directly on the LED chip being the light-emitting element 11 or on the package. With this, light loss due to interface reflection is reduced, allowing efficiency in light utilization to be further enhanced, as compared with a case where the plurality of pillars 21 and the spectroscopic film 23 are provided on the support member 22 as in the light-emitting device 1 of the embodiment described above.

### 6. Modification 5

FIG. 14 illustrates an example of a schematic cross-sectional configuration of a light-emitting device 1E according to Modification 5 of the present disclosure. FIG. 15 illustrates another example of a schematic cross-sectional configuration of the light-emitting device 1E according to Modification 5 of the present disclosure. FIG. 16 illustrates another example of a schematic cross-sectional configuration of the light-emitting device 1E according to Modification 5 of the present disclosure. Similarly to the light-emitting device 1 in the embodiment described above, the light-emitting device 1E is, for example, suitably used for the display pixel 123 of the image display apparatus 100.

In the embodiment described above, an example is described in which one end surface (surface 21S2) of each of the plurality of pillars 21 included in the wavelength converter 20 and the light extraction surface 10S of the light source section 10 are disposed opposed against each other, however the present disclosure is not limited to this. The light source section 10 may be disposed, for example, in a vertical direction with respect to an optical axis of light output from the plurality of pillars 21.

Specifically, as illustrated in FIG. 14, a side surface of the plurality of pillars 21 and the light extraction surface 10S of the light source section 10 may be disposed opposed against each other. Alternatively, as illustrated in FIG. 15, the light source section 10 may be disposed, in which the support member 22 serves as a light-guiding plate and a side surface of the support member 22 and the light extraction surface 10S of the light source section 10 are opposed against each other. Alternatively, as illustrated in FIG. 16, the light source section 10 may be provided, in which a dichroic mirror 31 that selectively reflects the excitation light EL to the surface 21S1 side is disposed, the surface 21S1 being a light output surface of the plurality of pillars 21 and the excitation light EL enters the plurality of pillars 21 from the surface 21S1 side.

As described above, in the light-emitting device 1E of the present modification, the light source section 10 is disposed in a vertical direction with respect to an optical axis of light output from the plurality of pillars 21. With this, the excitation light EL and light L converted by wavelength conversion in the plurality of pillars 21 are separated, allowing color purity of light output from the light-emitting device 1C to be enhanced.

### 7. Modification 6

FIG. 17 illustrates an example of a schematic cross-sectional configuration of a light-emitting device 1F according to Modification 6 of the present disclosure. Similarly to the light-emitting device 1 in the embodiment described above, the light-emitting device 1F is, for example, suitably used for the display pixel 123 of the image display apparatus 100.

On the surface 21S1 side, the surface 21S1 being the light output surface of the plurality of pillars 21 included in the wavelength converter 20, for example, a spectroscopic film 24 that selectively reflects the excitation light EL may be provided, as illustrated in FIG. 17.

As described above, in the light-emitting device 1F of the present modification, the spectroscopic film 24 that selectively reflects the excitation light EL is provided on the surface 21S1 side, the surface 21S1 being the light output surface of the plurality of pillars 21 included in the wavelength converter 20. With this, for example, the excitation light EL having not been converted by wavelength conversion in the plurality of pillars 21 is possible to be returned in the pillars 21 again, allowing more excitation light EL to be subjected to absorption light emission in the phosphors. Thus, afterglow ratio of the excitation light EL included in fluorescence light emission output from the light-emitting device 1C is reduced, allowing color purity of light to be enhanced.

Further, as the spectroscopic film 24, an optical film having a spectral characteristic that reflects a portion of fluorescence together with the excitation light EL may be used to allow the light (fluorescence) confinement effect in the plurality of pillars 21 to be increased. As described above, the fluorescence confinement in the plurality of pillars 21 is increased, allowing polarized fluorescence with higher directivity to be obtained. Note that, in a case of the configuration as described above, the spectroscopic film 24 is preferable to have a reflectance of 90% or more with respect to the excitation light EL and have a reflectance of 40% or more with respect to the fluorescence. Further, the light source section 10 is preferable to be driven by pulse drive to increase the peak power of the excitation light EL to be output.

### 8. Modification 7

FIG. 18 illustrates an example of a schematic cross-sectional configuration of a light-emitting device 1G according to Modification 7 of the present disclosure. Similarly to the light-emitting device 1 in the embodiment described above, the light-emitting device 1G is, for example, suitably used for the display pixel 123 of the image display apparatus 100.

The wavelength converter 20 may have a multilevel structure. Specifically, for example as illustrated in FIG. 18, a structure may be used in which a wavelength converter 20A and a wavelength converter 20B are stacked, the wavelength converter 20A including the plurality of pillars 21 provided on the surface 22S1 of the support member 22 and the spectroscopic film provided for each of the pillars 21, the wavelength converter 20B including a plurality of pillars 25 provided on a surface 26S1 of a support member 26 and a spectroscopic film 27 provided for each of the pillars 25. In this case, the plurality of pillars 25 disposed on the upper level is disposed in a region where, in plan view, the plurality of pillars 21 disposed on the lower level is not provided.

As described above, in the present modification, the wavelength converter 20 has the multilevel structure (for example, two-level structure with the wavelength converters 20A and 20B), and the plurality of pillars 25 disposed on the upper level is disposed in a region where, in plan view, the plurality of pillars 21 disposed on the lower level is not provided. With this, the excitation light penetrated without entering the plurality of pillars 21 in the wavelength converter 20A of the lower level is converted by wavelength conversion in the plurality of pillars 25 in the wavelength converter 20B of the upper level. Thus, color purity of light output from the light-emitting device 1G is possible to be enhanced. Further, efficiency in light utilization is possible to be further enhanced.

Note that the plurality of pillars 21 included in the wavelength converter 20A and the plurality of pillars 25 included in the wavelength converter 20B may each be configured to convert the excitation light EL into light with the same wavelength or may be configured to convert the excitation light EL into light with wavelengths different from each other.

For example, with use of blue light as the excitation light EL, the plurality of pillars 21 may convert the excitation light EL into red light and the plurality of pillars 25 may convert the excitation light EL into green light. This allows white light to be obtained from the light-emitting device 1G. Alternatively, one of the plurality of pillars 21 and plurality of pillars 25 may have a configuration in which the excitation light EL is converted by wavelength conversion into visible light and the other one may have a configuration in which the excitation light EL is converted by wavelength conversion into near infrared, and this allows light for sensing to be obtained, at the same time of obtaining visible light, from the light-emitting device 1G.

### 9. Modification 8

FIG. 19 illustrates an example of a schematic cross-sectional configuration of a light-emitting device 1H according to Modification 8 of the present disclosure. Similarly to the light-emitting device 1 in the embodiment described above, the light-emitting device 1H is, for example, suitably used for the display pixel 123 of the image display apparatus 100.

Between the light source section 10 and the wavelength converter 20, for example, a beam forming element 32 may be disposed. Examples of the beam forming element 32 includes a microlens array (MLA) and a micro free optics (MFO).

As described above, in the light-emitting device 1H of the present modification, the beam forming element 32 is disposed between the light source section 10 and the wavelength converter 20. With this, beam forming is performed for the excitation light EL output from the light source section 10, allowing intensity distribution of light output from the wavelength converter 20 to be uniformed, as compared with the light-emitting device 1 of the embodiment described above or the like. Further, a peak value of density of the excitation light EL is decreased and averaged, and thus enhancement in fluorescence conversion efficiency is possible to be expected.

### 10. Modification 9

FIG. 20 illustrates an example of a schematic cross-sectional configuration of a light-emitting device 11 according to Modification 9 of the present disclosure. Similarly to the light-emitting device 1 in the embodiment described above, the light-emitting device 11 is, for example, suitably used for the display pixel 123 of the image display apparatus 100.

In the embodiment described above, an example is described in which the wavelength converter 20 has space between adjacent pillars 21, however the present disclosure is not limited to this. A partition wall 28 may be provided between adjacent pillars 21. For example, as illustrated in FIG. 20, the partition wall 28 may be formed integrally with the support member 22. Specifically, for example, a plurality of openings 28H each having a predetermined shape may be formed in the support member 22, for example, the spectroscopic film 23 may be formed on the bottom surface of each of the openings 28H, and then the openings may be filled with phosphors to form the plurality of pillars 21. Filling the openings 28H with phosphors may be performed using, for example, ink jet printing or spin coding. Alternatively, phosphor synthesis (such as perovskite) may be performed in the openings 28H to fill the openings 28H with phosphors.

As described above, in the light-emitting device 11 of the present modification, for example, the partition wall 28 is provided on the support member 22, and the openings 28H are filled with phosphors to form the plurality of pillars 21. With this, heat generated in the pillars 21 is radiated through the partition wall 28, and thus a local temperature rise of the phosphors included in the pillars 21 is reduced. Thus, highly efficient fluorescence conversion is possible to be achieved.

### 11. Modification 10

FIG. 21 is a perspective diagram illustrating an example of a configuration of the wavelength converter 20 according to Modification 10 of the present disclosure. In the embodiment described above, an example is described in which the plurality of pillars 21 is disposed standing on the support member 22, however the plurality of three-dimensional structures included in the wavelength converter 20 is not limited to this. For example, as illustrated in FIG. 21, the wavelength converter 20 may have, for example, a configuration (grating structure) in which a plurality of three-dimensional structures that is each disposed standing on the support member 22 and that is each extending in the Y-axis direction is arranged side by side in the X-axis direction. This allows the manufacturing cost to be reduced, as compared with the embodiment described above.

Note that, as in the embodiment described above, the wavelength converter 20 including the plurality of pillars 21 makes it possible to obtain directional light emission in two axis directions, whereas the wavelength converter 20 having the grating structure of the present modification makes it possible to obtain directional light emission in one axis direction only.

### 12. Modification 11

FIGS. 22A to 22C are each a diagram schematically illustrating an example of a planar configuration of the plurality of pillars included in the wavelength converter 20 according to Modification 11 of the present disclosure. In the embodiment described above, an example including one type of pillars 21 is described in which each of the plurality of pillars 21 included in the wavelength converter 20 outputs light with the same color wavelength, however the present disclosure is not limited to this. Further, in Modification 7, an example is described in which the wavelength converter 20 has the multilevel structure with the wavelength converter 20A disposed on the lower level and the wavelength converter 20B disposed on the upper level that perform conversion into wavelengths different from each other and, for example, white light is obtained, however the present disclosure is not limited to this.

The wavelength converter 20 may have a configuration that two types of pillars 21 are disposed standing on the support member 22, light with wavelengths different from each other being output from the two types of pillars 21. For example, as illustrated in FIG. 22A, the wavelength converter 20 may have a configuration that a plurality of pillars 21R and a plurality of pillars 21G are disposed standing on the support member 22, the plurality of pillars 21R converting, for example, the excitation light EL into red light, the plurality of pillars 21G converting, for example, the excitation light EL into green light. With respect to the arrangement of each of the plurality of pillars 21R and the plurality of pillars 21B, for example, four pillars 21R arranged in two columns and two rows and four pillars 21G arranged in two columns and two rows may be arranged in hound's tooth check-like, for example as illustrated in FIG. 22B. This allows white light to be obtained, without the multilevel structure.

Further, the wavelength converter 20 may have a configuration that three or more types of pillars 21 are disposed standing on the support member 22, light with wavelengths different from each other being output from the three or more types of pillars 21. For example, in a case where the light-emitting element 11 that outputs ultraviolet ray as the excitation light EL is used for the light source section 10, three types of pillars may be arranged in honeycomb-shape as illustrated in FIG. 22C, the three types of pillars being pillars 21R that convert the excitation light EL into red light, pillars 21G that convert the excitation light EL into green light, and pillars 21B that convert the excitation light EL into blue light. As described above, with the wavelength converter 20 configured using three or more types of pillars 21, more detailed spectral adjustment is possible to be made for light output from the light-emitting device 1.

### 13. Application Example 1

FIG. 23 is a perspective diagram illustrating an example of a schematic configuration of an image display apparatus (image display apparatus 100). The image display apparatus 100 is a so-called LED display. In the image display apparatus 100, the light-emitting device (for example, light-emitting device 1) of the present disclosure is used as a display pixel. The image display apparatus 100 includes a display panel 110 and a control circuit 140 that drives the display panel 110, for example as illustrated in FIG. 3.

The display panel 110 includes a mounting substrate 120 and a counter substrate 130 overlapping with each other. A surface of the counter substrate 130 is a picture display surface including a display region (display region 100A) at the center part and a frame region 100B around the display region, the frame region 100B being a non-display region.

FIG. 24 illustrates an example of a wiring layout of a region, corresponding to the display region 100A, of a surface on the counter substrate 130 side of the mounting substrate 120. The region, corresponding to the display region 100A, of the surface of the mounting substrate 120 is provided with, for example as illustrated in FIG. 24, a plurality of data wirings 121 formed extending in a predetermined direction, the plurality of data wirings 121 arranged in parallel at predetermined pitches. The region, corresponding to the display region 100A, of the surface of the mounting substrate 120 is further provided with, for example, a plurality of scanning wirings 122 formed extending in a direction intersecting with (for example, orthogonal to) the data wirings 121, the plurality of scanning wirings 122 arranged in parallel at predetermined pitches. The data wirings 121 and the scanning wirings 122 include, for example, an electric conductive material such as Cu.

The scanning wirings 122 are formed, for example, on the outermost layer. For example, the scanning wirings 122 are formed on an insulation layer (not illustrated) formed on a base surface. Note that the base of the mounting substrate 120 includes, for example, a silicon substrate or a resin substrate, and that the insulation layer on the base includes, for example, SiN, SiO, aluminum oxide (AlO), or resin material. Meanwhile, the data wirings 121 are formed in a layer (for example, layer lower than the outermost layer) different from the outermost layer including the scanning wirings 122. For example, the data wirings 121 are formed in the insulation layer on the base.

A vicinity of a point at which any one of the data wirings 121 and any one of the scanning wirings 122 intersect corresponds to the display pixel 123. A plurality of the display pixels 123 is disposed in matrix in the display region 100A. For example, the light-emitting device 1 is mounted on each display pixel 123.

The light-emitting device 1 is, for example, provided with a pair of terminal electrodes for each of the color pixels Pr, Pg, and Pb, or provided with one of the pair of the terminal electrodes disposed common to the color pixels Pr, Pg, and Pb and the other one disposed for each of the color pixels Pr, Pg, and Pb. The one terminal electrode is electrically connected to any one of the data wirings 121 and the other terminal electrode is electrically connected to any one of the scanning wirings 122. For example, the one terminal electrode is electrically connected to a pad electrode 121B at a tip of a branch 121 A provided for any one of the data wirings 121. Further, for example, the other terminal electrode is electrically connected to a pad electrode 122B at a tip of a branch 122 A provided for any one of the scanning wirings 122.

Each of the pad electrodes 121B and 122B is formed, for example, on the outermost layer, and provided for a part where each light-emitting device 1 is mounted on, for example as illustrated in FIG. 24. Here, each of the pad electrodes 121B and 122B includes, for example, an electric conductive material such as Au (gold).

The mounting substrate 120 is further provided with, for example, a plurality of posts (not illustrated) restricting a gap between the mounting substrate 120 and the counter substrate 130. The posts may be provided in a region opposed against the display region 100A or may be provided in a region opposed against the frame region 100B.

The counter substrate 130 includes, for example, a glass substrate or a resin substrate. A surface on the light-emitting device 1 side of the counter substrate 130 may be flat, but preferably be a rough surface. The rough surface may be provided over a whole of a region opposed against the display region 100A or may be provided only in a region opposed against the display pixel 123. The rough surface that light emitted from the color pixels Pr, Pg, and Pb enters has fine irregularities. The irregularities of the rough surface are possible to be produced by, for example, sand blasting or dry etching.

The control circuit 140 drives each display pixel 123 (each light-emitting device 1) on the basis of a picture signal. The control circuit 140 includes, for example, a data driver that drives the data wirings 121 each connected to the display pixel 123 and a scanning driver that drives the scanning wirings 122 each connected to the display pixel 123. The control circuit 140 may be, for example as illustrated in FIG. 3, provided separately from the display panel 110 and connected to the mounting substrate 120 via a wiring, or may be mounted on the mounting substrate 120.

### 14. Application Example 2

FIG. 25 is a perspective diagram illustrating another configuration example of the image display apparatus (image display apparatus 200) using the light-emitting device (for example, light-emitting device 1) of the present disclosure. The image display apparatus 200 is a so-called tiling display, using a plurality of the light-emitting devices each with an LED as a light source. The image display apparatus 200 includes a display panel 210 and a control circuit 240 that drives the display panel 210, for example as illustrated in FIG. 25.

The display panel 210 includes a mounting substrate 220 and a counter substrate 230 overlapping with each other. A surface of the counter substrate 230 is a picture display surface including a display section at the center part and a frame section around the display section (both not illustrated), the frame section being a non-display region. The counter substrate 230 is disposed at a position opposed against the mounting substrate 220, with a predetermined gap interposed, for example. Note that the counter substrate 230 may be in contact with an upper surface of the mounting substrate 220.

FIG. 26 schematically illustrates an example of a configuration of the mounting substrate 220. The mounting substrate 220 includes, for example as illustrated in FIG. 26, a plurality of unit substrates 250 laid in a tile-like shape. Note that, in FIG. 26, an example is described in which the mounting substrate 220 includes nine unit substrates 250, however the number of the unit substrates 250 may be ten or more, or may be eight or less.

FIG. 27 illustrates an example of a configuration of each unit substrate 250. The unit substrate 250 includes, for example, a plurality of the light-emitting devices 1 laid in a tile-like shape and a support substrate 260 supporting the respective light-emitting devices 1. Each unit substrate 250 further includes a control substrate (not illustrated). The support substrate 260 includes, for example, a metal frame (metal plate) or a wiring substrate. In a case where the support substrate 260 includes the wiring substrate, the support substrate 260 is possible to serve as the control substrate. In this case, the support substrate 260, the control substrate, or both are electrically connected to the respective light-emitting devices 1.

### 15. Application Example 3

FIG. 28 illustrates an external appearance of a transparent display 300. The transparent display 300 includes, for example, a display section 310, operation sections 311, and a housing 312. For the display section 310, the light-emitting device (for example, light-emitting device 1) of the present disclosure is used. The transparent display 300 allows an image or textual information to be displayed with a background of the display section 310 seen through.

For a mounting substrate of the transparent display 300, a substrate having optical transparency is used. Each electrode provided in the light-emitting device 1 is, similarly to the mounting substrate, formed using an electric conductive material having optical transparency. Alternatively, each electrode has a structure difficult to be visually recognized, by complementing a wiring width or reducing the wiring in thickness. Further, for example, the transparent display 300 allows black display with a liquid crystal layer including a drive circuit overlapped, and allows switching between transparency and black display with the illumination direction of the liquid crystal controlled.

The present disclosure has been described as above taking the embodiment, Modifications 1 to 11, and Application Examples 1 to 3, but the present disclosure is not limited to such embodiments described above and various modifications are possible. For example, in the embodiments and the like described above, an example is described in which light output from the light-emitting element 11 is blue light or ultraviolet ray, however the present disclosure is not limited to this.

Further, in the embodiments and the like described above, an example is described in which the LED chip including the mesa part M is used as the light-emitting element 11, the shape of the LED chip is not limited to this.

Further, the light-emitting device (for example, light-emitting device 1) described in the embodiments and the like described above is not limited to an AR headset or a compact projector but is possible to be used for an illumination apparatus, various sensors, a medical and industrial apparatus, or the like.

Note that the effect described in the present specification is only an example and by no means limited. Another effect may be conceivable.

Note that the present disclosure may have a configuration as below. According to a technique of the present disclosure with the configuration below, a wavelength converter including a plurality of three-dimensional structures each including a phosphor, each of the plurality of three-dimensional structures standing on a first surface of a support member and having a height in a standing direction equal to or larger than a width in an in-plane direction of the first surface, is provided, and a first spectroscopic film that is disposed on a first end surface side of the plurality of three-dimensional structures facing the first surface of the support member and that reflects light converted by wavelength conversion in the plurality of three-dimensional structures is provided. With this, light converted by wavelength conversion in the plurality of three-dimensional structures is confined in the plurality of three-dimensional structures. Thus, a light-emitting device with high directivity and an image display apparatus are possible to be provided.

(1)

A light-emitting device including:
a light source section that outputs excitation light;
a support member that has optical transparency and that includes a first surface and a second surface opposed to each other;
a wavelength converter including a plurality of three-dimensional structures each including a phosphor, each of the plurality of three-dimensional structures standing on the first surface of the support member and having a height in a standing direction equal to or larger than a width in an in-plane direction of the first surface; and
a first spectroscopic film that is disposed on a first end surface side of the plurality of three-dimensional structures facing the first surface of the support member and that reflects light converted by wavelength conversion in the plurality of three-dimensional structures.
   (2)

The light-emitting device according to (1), in which
the first spectroscopic film is selectively provided on the first surface of the support member facing the first end surface of the plurality of three-dimensional structures.
   (3)

The light-emitting device according to (2), in which
a light shielding film that blocks the excitation light is provided on the first surface of the support member where the first spectroscopic film is not formed.
   (4)

The light-emitting device according to any one of (1) to (3), in which the first spectroscopic film is provided over a whole surface of the first surface of the support member.

(5)

The light-emitting device according to any one of (1) to (3), in which
the first spectroscopic film is provided over a whole surface of the second surface of the support member.
   (6)

The light-emitting device according to any one of (1) to (5), in which
the light source section includes a light extraction surface having a protection layer, the protection layer serving as the support member.
   (7)

The light-emitting device according to any one of (1) to (6), in which
each of the plurality of three-dimensional structures has a pillar structure.
   (8)

The light-emitting device according to any one of (1) to (7), in which
the plurality of three-dimensional structures is disposed in matrix, in hound's tooth check, or in honeycomb-shape.
   (9)

The light-emitting device according to any one of (1) to (8), in which
the plurality of three-dimensional structures includes a plurality of first three-dimensional structures and a plurality of second three-dimensional structures, each of the plurality of first three-dimensional structures including a phosphor that converts the excitation light into light with a first wavelength, each of the plurality of second three-dimensional structures including a phosphor that converts the excitation light into light with a second wavelength different from the first wavelength.
   (10)

The light-emitting device according to any one of (1) to (6), in which
the plurality of three-dimensional structures has a grating structure.
   (11)

The light-emitting device according to any one of (1) to (10), in which
the plurality of three-dimensional structures further includes, on a second end surface side, a second spectroscopic film that reflects the excitation light, the second end surface being opposite to the first end surface and being a light extraction surface.
   (12)

The light-emitting device according to any one of (1) to (11), in which
the light source section is disposed to oppose the second surface of the support member.
   (13)

The light-emitting device according to any one of (1) to (12), in which
the light source section is disposed in a side surface direction of the plurality of three-dimensional structures.
   (14)

The light-emitting device according to any one of (1) to (12), in which
the light source section is disposed for the excitation light to enter from a second end surface side, the second end surface being opposite to the first end surface of the plurality of three-dimensional structures and being a light extraction surface.
   (15)

The light-emitting device according to any one of (1) to (14), in which
the wavelength converter includes a first wavelength converter and a second wavelength converter, the first wavelength converter including the plurality of three-dimensional structures disposed at predetermined intervals, the second wavelength being converter stacked on the first wavelength converter and including the plurality of three-dimensional structures disposed in a region where, in plan view, the plurality of three-dimensional structures included in the first wavelength converter is not disposed.
   (16)

The light-emitting device according to (15), in which
light converted by wavelength conversion in the first wavelength converter and light converted by wavelength conversion in the second wavelength converter have the same wavelength as each other.
   (17)

The light-emitting device according to (15), in which
light converted by wavelength conversion in the first wavelength converter and light converted by wavelength conversion in the second wavelength converter have a different wavelength from each other.
   (18)

The light-emitting device according to any one of (1) to (17), further comprising
a beam forming element between the light source section and the wavelength converter.
   (19)

The light-emitting device according to any one of (1) to (18), in which
a partition wall is provided between the plurality of three-dimensional structures.
   (20)

An image display apparatus that includes a plurality of light-emitting devices arranged in an array, each of the plurality of light-emitting devices including:
a light source section that outputs excitation light;
a support member that has optical transparency and that includes a first surface and a second surface opposed to each other;
a wavelength converter including a plurality of three-dimensional structures each including a phosphor, each of the plurality of three-dimensional structures standing on the first surface of the support member and having a height in a standing direction equal to or larger than a width in an in-plane direction of the first surface; and
a first spectroscopic film that is disposed on a first end surface side of the plurality of three-dimensional structures facing the first surface of the support member and that reflects light converted by wavelength conversion in the plurality of three-dimensional structures.

The present application claims the benefit of Japanese Priority Patent Application JP2022-059213 filed with the Japan Patent Office on Mar. 31, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A light-emitting device, comprising:
a light source section that outputs excitation light;
a support member that has optical transparency and that includes a first surface and a second surface opposed to each other;
a wavelength converter including a plurality of three-dimensional structures each including a phosphor, each of the plurality of three-dimensional structures standing on the first surface of the support member and having a height in a standing direction equal to or larger than a width in an in-plane direction of the first surface; and
a first spectroscopic film that is disposed on a first end surface side of the plurality of three-dimensional structures facing the first surface of the support member and that reflects light converted by wavelength conversion in the plurality of three-dimensional structures.

2. The light-emitting device according to claim 1, wherein
the first spectroscopic film is selectively provided on the first surface of the support member facing the first end surface of the plurality of three-dimensional structures.

3. The light-emitting device according to claim 2, wherein
a light shielding film that blocks the excitation light is provided on the first surface of the support member where the first spectroscopic film is not formed.

4. The light-emitting device according to claim 1, wherein
the first spectroscopic film is provided over a whole surface of the first surface of the support member.

5. The light-emitting device according to claim 1, wherein
the first spectroscopic film is provided over a whole surface of the second surface of the support member.

6. The light-emitting device according to claim 1, wherein
the light source section includes a light extraction surface having a protection layer, the protection layer serving as the support member.

7. The light-emitting device according to claim 1, wherein
each of the plurality of three-dimensional structures has a pillar structure.

8. The light-emitting device according to claim 1, wherein
the plurality of three-dimensional structures is disposed in matrix, in hound's tooth check, or in honeycomb-shape.

9. The light-emitting device according to claim 1, wherein
the plurality of three-dimensional structures includes a plurality of first three-dimensional structures and a plurality of second three-dimensional structures, each of the plurality of first three-dimensional structures including a phosphor that converts the excitation light into light with a first wavelength, each of the plurality of second three-dimensional structures including a phosphor that converts the excitation light into light with a second wavelength different from the first wavelength.

10. The light-emitting device according to claim 1, wherein
the plurality of three-dimensional structures has a grating structure.

11. The light-emitting device according to claim 1, wherein
the plurality of three-dimensional structures further includes, on a second end surface side, a second spectroscopic film that reflects the excitation light, the second end surface being opposite to the first end surface and being a light extraction surface.

12. The light-emitting device according to claim 1, wherein
the light source section is disposed to oppose the second surface of the support member.

13. The light-emitting device according to claim 1, wherein
the light source section is disposed in a side surface direction of the plurality of three-dimensional structures.

14. The light-emitting device according to claim 1, wherein
the light source section is disposed for the excitation light to enter from a second end surface side, the second end surface being opposite to the first end surface of the plurality of three-dimensional structures and being a light extraction surface.

15. The light-emitting device according to claim 1, wherein
the wavelength converter includes a first wavelength converter and a second wavelength converter, the first wavelength converter including the plurality of three-dimensional structures disposed at predetermined intervals, the second wavelength being converter stacked on the first wavelength converter and including the plurality of three-dimensional structures disposed in a region where, in plan view, the plurality of three-dimensional structures included in the first wavelength converter is not disposed.

16. The light-emitting device according to claim 15, wherein
light converted by wavelength conversion in the first wavelength converter and light converted by wavelength conversion in the second wavelength converter have a same wavelength as each other.

17. The light-emitting device according to claim 15, wherein
light converted by wavelength conversion in the first wavelength converter and light converted by wavelength conversion in the second wavelength converter have a different wavelength from each other.

18. The light-emitting device according to claim 1, further comprising
a beam forming element between the light source section and the wavelength converter.

19. The light-emitting device according to claim 1, wherein
a partition wall is provided between the plurality of three-dimensional structures.

20. An image display apparatus that includes a plurality of light-emitting devices arranged in an array, each of the plurality of light-emitting devices comprising:
a light source section that outputs excitation light;
a support member that has optical transparency and that includes a first surface and a second surface opposed to each other;
a wavelength converter including a plurality of three-dimensional structures each including a phosphor, each of the plurality of three-dimensional structures standing on the first surface of the support member and having a height in a standing direction equal to or larger than a width in an in-plane direction of the first surface; and
a first spectroscopic film that is disposed on a first end surface side of the plurality of three-dimensional structures facing the first surface of the support member and that reflects light converted by wavelength conversion in the plurality of three-dimensional structures.
